(19) United States
(12) Patent Application Publication
(10) Pub. No.: US 2012/0269012 A1
(43) Pub. Date: Oct. 25, 2012

(54) SEMICONDUCTOR INTEGRATED CIRCUIT AND METHOD FOR DRIVING THE SAME

(76) Inventor: Ga-Young LEE, Gyeonggi-do (KR)

(21) Appl. No.: 13/190,925

(22) Filed: Jul. 26, 2011

(30) Foreign Application Priority Data
Apr. 25, 2011 (KR) 10-2011-0038515

(51) Int. Cl. G11C 7/00; G11C 8/18

(52) U.S. Cl. 365/189.16; 365/193; 365/189.11

(57) ABSTRACT

A semiconductor integrated circuit includes a first signal generator configured to generate a third active signal that is selectively enabled in a first duration in response to a first active signal enabled during the first duration and a second active signal enabled during at least one second duration within the first duration an internal circuit configured to cease operating in response to the third active signal, and a second signal generator configured to generate the second active signal in response to a mode determination signal and a strobe signal.

### CROSS-REFERENCE TO RELATED APPLICATIONS

The present application claims priority of Korean Patent Application No. 10-2011-0038515, filed on Apr. 25, 2011, which is incorporated herein by reference in its entirety.

### BACKGROUND

1. Field

Exemplary embodiments of the present invention relate to a semiconductor designing technology, and more particularly, to a control circuit for controlling a sense amplifier, and a method for driving the control circuit.

2. Description of the Related Art

Descriptions will be made with reference to, for example, a semiconductor memory device.

FIG. 1 is a circuit diagram illustrating a write path of a conventional semiconductor memory device.

Referring to FIG. 1, the write path includes a write driver 10, a first switch 20, a second switch 30, a bit line sense amplifier (BLSA) 40, and a memory cell 50. The write driver 10 receives a data received through a pair of global input/output lines GIO and/GIO and outputs the data through a pair of local input/output lines LIO and /LIO. The first switch 20 selectively couples the pair of local input/output lines LIO and /LIO with a pair of segment input/output lines SIO and/SIO in response to an input/output line coupling signal IOSW. The second switch 30 selectively couples the pair of segment input/output lines SIO and /SIO with a pair of bit lines BL and /BL in response to a column selection signal YI<0>. The bit line sense amplifier 40 selectively amplifies the data loaded on the pair of bit lines BL and /BL in response to a first driving signal SAN and a second driving signal SAP. The memory cell 50 stores the data loaded on the pair of bit lines BL and /BL as a word line SWL is enabled.

FIG. 2 is a circuit diagram of a control circuit for generating the first driving signal SAN and the second driving signal SAP applied to the bit line sense amplifier shown in FIG. 1 to control the bit line sense amplifier 40.

Referring to FIG. 2, the circuit for generating the first driving signal SAN and the second driving signal SAP includes a selection signal generator 60 and a driving signal generator 70. The selection signal generator 60 generates a selection signal SEL in response to an upper matrix selection signal UP_MAT_SEL and a lower matrix selection signal ORG_MAT_SEL. The driving signal generator 70 generates the first driving signal SAN and the second driving signal SAP in response to the selection signal SEL and first and second enable signals SAN_EN and SAP_EN.

Herein, the selection signal generator 60 enables the selection signal SEL when the upper matrix selection signal UP_MAT_SEL or the lower matrix selection signal ORG_MAT_SEL is enabled. For example, the selection signal generator 60 outputs a selection signal SEL of a logic high level when the upper matrix selection signal UP_MAT_SEL or the lower mat selection signal ORG_MAT_SEL is in a logic low level.

The driving signal generator 70 enables the first driving signal SAN and the second driving signal SAP when the selection signal SEL is enabled while the first and second enable signals SAN_EN and SAP_EN are enabled. For example, the driving signal generator 70 outputs first and second driving signals SAN and SAP of a logic high level when the first and second enable signals SAN_EN and SAP_EN are in a logic high level and the selection signal SEL is in a logic high level.

Hereinafter, the operation of the write path of the semiconductor memory device having the above structure is described.

FIG. 3 is a timing diagram illustrating the operation of the write path of the conventional semiconductor memory device shown in FIG. 1.

Referring to FIG. 3, as an active command ACT is applied, the input/output line coupling signal IOSW is enabled to a logic high level. Then the first switch 20 is turned on so as to couple the pair of local input/output lines LIO and /LIO with the pair of segment input/output lines SIO and /SIO. Then, as the corresponding word line SWL is enabled, a seed data stored in the memory cell 50 is charge-shared between a capacitor C of the memory cell 50 and a capacitor of the pair of bit lines BL and /BL, which is in a floating state because the bit line sense amplifier 40 is not driven at this time.

Subsequently, when an upper matrix or a lower matrix which shares the bit line sense amplifier 40 is selected while the first and second enable signals SAN_EN and SAP_EN are in an enabled state, the first and second driving signals SAN and SAP are enabled and the bit line sense amplifier 40 amplifies the data loaded on the pair of bit lines BL and /BL.

In this state, when a write command WT is applied, a data to be written by the write driver 10 through the pair of local input/output lines LIO and /LIO is loaded, and the data loaded on the pair of local input/output lines LIO and /LIO is loaded on the pair of segment input/output lines SIO and /SIO, too. This is because the first switch 20 is already turned on.

Subsequently, when the column selection signal YI<0>is enabled to a logic high level, the second switch 30 is turned on and the data loaded on the pair of segment input/output lines SIO and /SIO is loaded on the pair of bit lines BL and /BL and eventually loaded on the memory cell 50.

However, the write path of the conventional semiconductor memory device may have the following drawbacks.

During a write operation, as the active command ACT is applied, the bit line sense amplifier 40 is driven and the seed data, which is charge-shared between the pair of bit lines BL and /BL, is amplified. The pair of bit lines BL and /BL then maintains the amplified voltage level. In this state, the data to be written is loaded on the pair of bit lines BL and /BL. Herein, when the data to be written has an opposite phase to the phase of the seed data, the write driver 10 has to turn over the seed data loaded on the pair of bit lines BL and /BL into the data to be written through fighting with the bit line sense amplifier 40. However, since the bit line sense amplifier 40 is strongly driving the pair of bit lines BL and /BL at a level corresponding to the seed data through a latch operation, it may be difficult for the write driver 10 to turn over the pair of bit lines BL and /BL to the level corresponding to the data to be written during a duration where the column selection signal YI<0>is enabled. In this case, the data to be written may not be stably stored in the memory cell 50 and thus, an undesirable data may be read during a subsequent read operation.

### SUMMARY

Exemplary embodiments of the present invention are directed to a semiconductor integrated circuit which is capable of limiting the operation of a bit line sense amplifier (BLSA) during a write operation, and a method for driving the semiconductor integrated circuit.

In accordance with an exemplary embodiment of the present invention, a semiconductor integrated circuit includes a first signal generator configured to generate a third active signal that is selectively enabled in a first duration in response to a first active signal enabled during the first duration and a second signal enabled during at least one second duration within the first duration, an internal circuit configured to cease operating in response to the third active signal, and a second signal generator configured to generate the second active signal in response to a mode determination signal and a strobe signal.

In accordance with another exemplary embodiment of the present invention, a semiconductor integrated circuit includes a driving signal generator configured to generate a first driving signal and a second driving signal that are selectively enabled during a first duration in response to first and second enable signals that are enabled during an active operation, an active command-based selection signal that is enabled during the first duration, and a control signal that is enabled during at least one second duration within the first duration, a bit line sense amplifier (BLSA) configured to be driven in response to the first driving signal and the second driving signal, wherein the BLSA ceases to sense when the first and second driving signals are active, and a control signal generator for generating the control signal in response to a mode determination signal and a column strobe signal.

The column strobe signal may be enabled in response to a burst length.

In accordance with yet another exemplary embodiment of the present invention, a method for driving a semiconductor integrated circuit includes entering a write mode, stopping an operation of a bit line sense amplifier in the write mode, loading a data on a pair of bit lines while the operation of the bit line sense amplifier is stopped, and writing the data loaded on the pair of bit lines in a memory cell.

The stopping of the operation of the bit line sense amplifier in the write mode may be performed during a column selection duration enabled in response to a burst length.

### BRIEF DESCRIPTION OF THE DRAWINGS

FIG. 1 is a circuit diagram illustrating a write path of a conventional semiconductor memory device.

FIG. 2 is a circuit diagram of a control circuit for controlling a bit line sense amplifier shown in FIG. 1.

FIG. 3 is a timing diagram illustrating the operation of the write path of the conventional semiconductor memory device shown in FIG. 1.

FIG. 4 is a block diagram illustrating a semiconductor memory device in accordance with an exemplary embodiment of the present invention.

FIG. 5A is a detailed block diagram showing a driving signal generator 110 shown in FIG. 4.

FIG. 5B is a diagram demonstrating a control signal generator shown in FIG. 4.

FIG. 5C is a diagram illustrating a selection signal generator shown in FIG. 4.

FIG. 6 is a timing diagram illustrating the operation of a write path of a semiconductor memory device in accordance with an exemplary embodiment of the present invention.

### DETAILED DESCRIPTION

Exemplary embodiments of the present invention will be described below in more detail with reference to the accompanying drawings. The present invention may, however, be embodied in different forms and should not be construed as limited to the embodiments set forth herein. Rather, these embodiments are provided so that this disclosure will be thorough and complete, and will fully convey the scope of the present invention to those skilled in the art. Throughout the disclosure, like reference numerals refer to like parts throughout the various figures and embodiments of the present invention.

In an exemplary embodiment of the present invention, a semiconductor memory device is described as an example.

Also herein, in the exemplary embodiments of the present invention, the same reference symbol was given to the same signal performing the same function as that of the conventional technology for the sake of convenience in description.

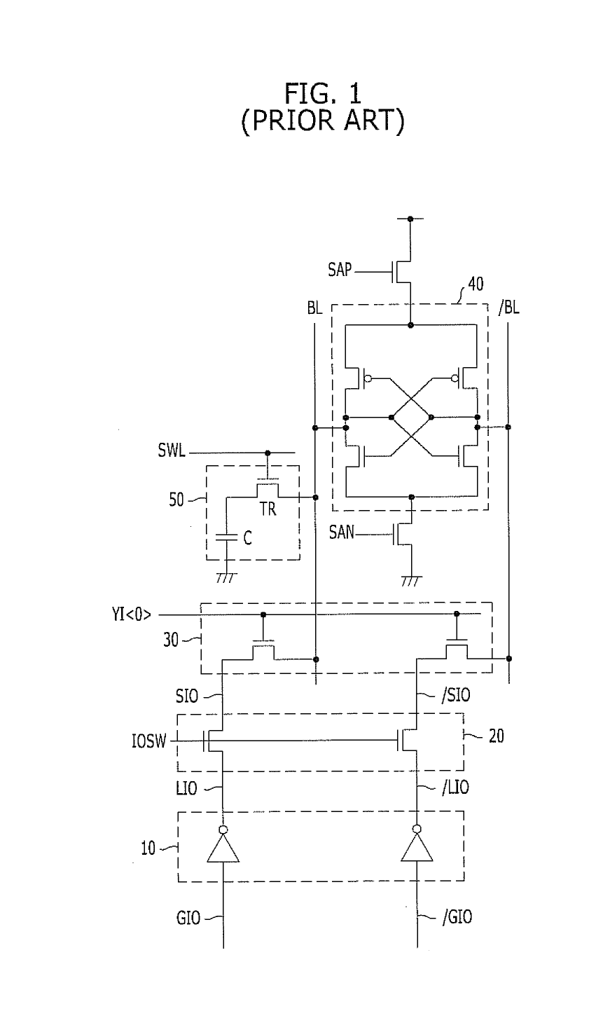

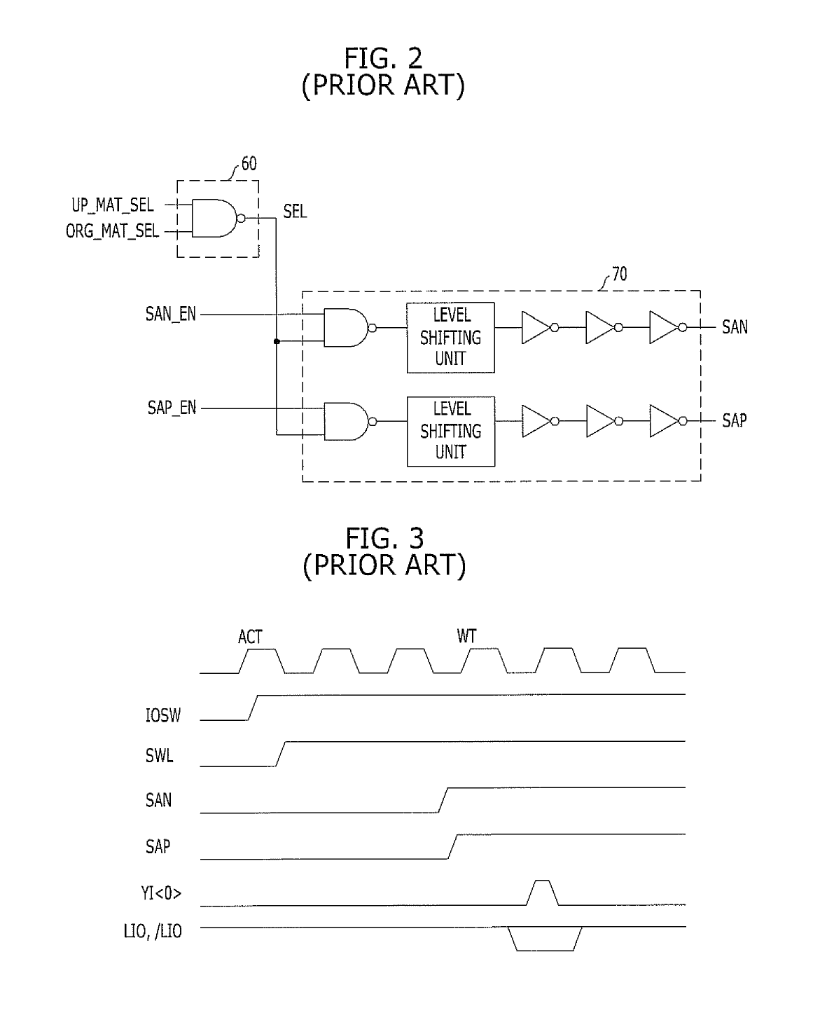

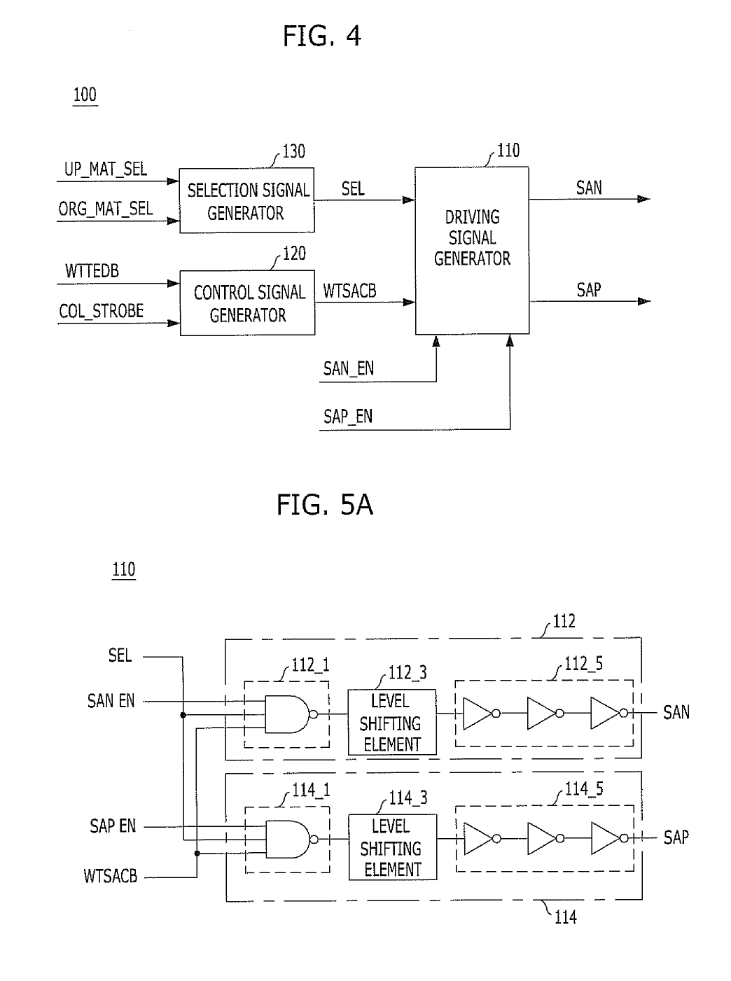

FIG. 4 is a block diagram illustrating a semiconductor memory device in accordance with an exemplary embodiment of the present invention. Herein, for the sake of convenience, in the semiconductor memory device, a control circuit 100 for controlling the bit line sense amplifier (BLSA) shown in FIG. 4 is illustrated in FIG. 1.

Referring to FIG. 4, the control circuit 100 for controlling a bit line sense amplifier 40 includes a driving signal generator 110, a control signal generator 120, and a selection signal generator 130.

The driving signal generator 110 generates a first driving signal SAN and a second driving signal SAP that are restrictively enabled during a first duration in response to first and second enable signals SAN_EN and SAP_EN, an active command-based selection signal SEL, and a control signal WTSACB. Here, the first and second enable signals SAN_EN and SAP_EN are enabled during an active operation, the active command-based selection signal SEL is enabled during the first duration, and the control signal WTSACB is enabled during at least one second duration within the first duration where the active command-based selection signal SEL is enabled. The control signal generator 120 generates the control signal WTSACB in response to a mode determination signal WTTEDB and a column strobe signal COL_STROBE. The selection signal generator 130 generates the active command-based selection signal SEL in response to an upper matrix selection signal UP_MAT_SEL and a lower matrix selection signal ORG_MAT_SEL.

Herein, the first driving signal SAN and the second driving signal SAP are signals for controlling the operation of the a bit line sense amplifier 40, and the mode determination signal WTTEDB is a signal for distinguishing a write mode and a read mode from each other. The column strobe signal COL_STROBE is a signal enabled in response to the burst length BL. For example, when the burst length is 8, first to eighth column selection signals YI<0:7>are sequentially enabled. Thus, the column strobe signal COL_STROBE is enabled eight times in the form of pulse. Also, the upper matrix selection signal UP_MAT_SEL and the lower matrix selection signal ORG_MAT_SEL are signals for selecting an upper matrix, including a memory cell block, and a lower matrix, including a memory cell block, that share the bit line sense amplifier 40, respectively. The upper matrix selection signal UP_MAT_SEL and the lower matrix selection signal ORG_MAT_SEL are enabled after an active command (not shown) is enabled.

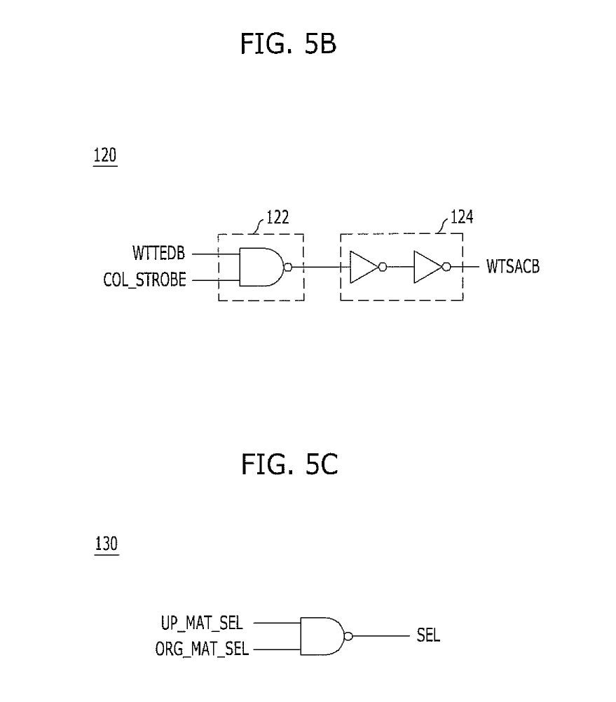

FIG. 5A is an internal block diagram of the driving signal generator 110 shown in FIG. 4.

Referring to FIG. 5A, the driving signal generator 110 includes a first driving signal generation unit 112 and a second driving signal generation unit 114. The first driving signal generation unit 112 generates the first driving signal SAN in response to the active command-based selection signal SEL, the first enable signal SAN_EN, and the control signal WTSACB. The second driving signal generation unit 114 generates the second driving signal SAP in response to the active command-based selection signal SEL, the second enable signal SAP_EN, and the control signal WTSACB,

Herein, the first driving signal generation unit 112 includes a first logic operation element 112_1, a first level shifting element 112_3, and a first output element 112_5. The first logic operation element 112_1 performs a logic operation onto the active command-based selection signal SEL, the first enable signal SAN_EN, and the control signal WTSACB. The first level shifting element 112_3 shifts the level of the output signal of the first logic operation element 112_1. The first output element 112_5 outputs the output signal of the first level shifting element 112_3 as the first driving signal SAN. Meanwhile, the first logic operation element 112_1 is formed of, for example, a NAND gate, and since the first level shifting element 112_3 is of a technology widely known to those skilled in the art, detailed description on the first level shifting element 112_3 is omitted for the sake of convenience. The first output element 112_5 is formed of an inverter chain including an odd number of inverters.

The second driving signal generation unit 114 includes a second logic operation element 114_1, a second level shifting element 114_3, and a second output element 114_5. The second logic operation element 114_1 performs a logic operation onto the active command-based selection signal SEL, the second enable signal SAP_EN, and the control signal WTSACB. The second level shifting element 114_3 shifts the level of the output signal of the second logic operation element 114_1. The second output element 114_5 outputs the output signal of the second level shifting element 114_3 as the second driving signal SAP. Meanwhile, the second logic operation element 114_1 is formed of, for example, a NAND gate, and since the second level shifting element 114_3 is of a technology widely known to those skilled in the art, detailed description on the second level shifting element 114_3 is omitted for the sake of convenience. The second output element 114_5 is formed of an inverter chain including an odd number of inverters.

FIG. 5B is a diagram of the control signal generator 120 shown in FIG. 4.

Referring to FIG. 5B, the control signal generator 120 includes a third logic operation element 122 and a third output element 124. The third logic operation element 122 performs a logic operation onto the mode determination signal WTTEDB and the column strobe signal COL_STROBE. The third output element 124 outputs an output signal of the third logic operation element 122 as the control signal WTSACB. Meanwhile, the third logic operation element 122 is formed of, for example, a NAND gate, and the third output element 124 is formed of an inverter chain including an even number of inverters.

FIG. 5C is a diagram of the selection signal generator 130 shown in FIG. 4.

Referring to FIG. 5C, the selection signal generator 130 includes, for example, a NAND gate for outputting the active command-based selection signal SEL by performing a NAND operation onto the upper mat selection signal UP_MAT_SEL and the lower mat selection signal ORG_MAT_SEL. Herein, both upper matrix selection signal UP_MAT_SEL and lower matrix selection signal ORG_MAT_SEL are used because the selection signal generator 130 has a structure that the upper memory cell matrix and the lower memory cell matrix, which are distinguished based on a certain bit line sense amplifier 40, share the bit line sense amplifier 40 with each other, and thus, the bit line sense amplifier 40 is driven when the upper matrix is selected and the bit line sense amplifier 40 is driven, when the lower matrix is selected.

Hereafter, a method for driving the semiconductor memory device having the above structure is described in accordance with an exemplary embodiment of the present invention.

First, the driving method of the semiconductor memory device 100 includes, for example, a first step of entering a write mode; a second step of stopping the operation of the bit line sense amplifier 40 in the write mode; a third step of loading a data on a pair of bit lines BL and /BL in the state that the bit line sense amplifier 40 stops operating; and a fourth step of writing the data loaded on the pair of bit lines BL and /BL in a memory cell 50. Herein, the second step of stopping the operation of the bit line sense amplifier 40 is performed in a column selection duration enabled in response to a burst length. The method of driving the semiconductor memory device 100 including the above-described steps is described in more detail with reference to FIGS. 1, 4, and 6, hereinafter.

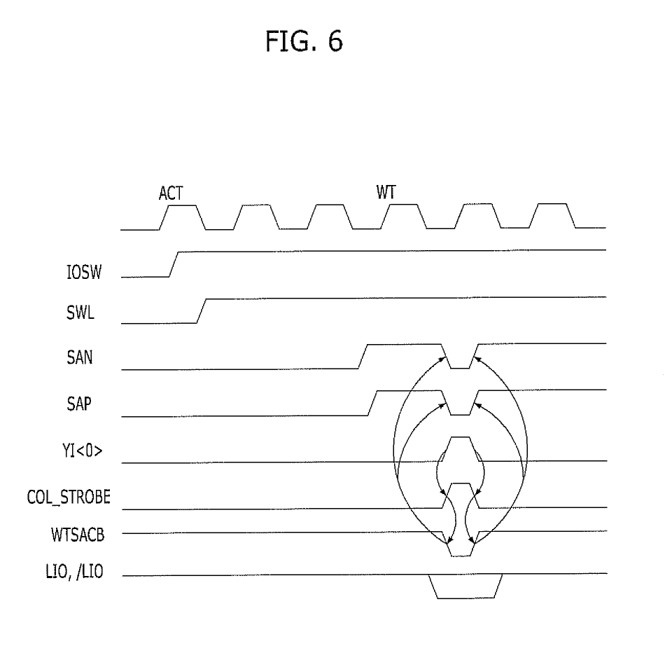

FIG. 6 is a timing diagram illustrating a method for driving the semiconductor memory device 100 in accordance with an exemplary embodiment of the present invention.

Referring to FIG. 6, as an active command ACT is applied, an input/output line coupling signal IOSW is enabled to a logic high level. Then, as a first switch 20 shown in FIG. 1 is turned on, a pair of local input/output lines LIO and /LIO and a pair of segment input/output lines SIO and /SIO are coupled with each other. As a corresponding word line SWL is enabled, a seed data stored in the memory cell 50 is charge-shared between a capacitor C of the memory cell 50 and a capacitor of the pair of bit lines BL and /BL, which is in a floating state because the bit line sense amplifier 40 is not driven at this time.

Subsequently, the first and second enable signals SAN_EN and SAP_EN are enabled to a logic high level, and when the upper matrix selection signal UP_MAT_SEL or the lower matrix selection signal ORG_MAT_SEL is enabled to a logic low level, the first driving signal

SAN and the second driving signal SAP are enabled to a logic high level. Herein, since the control signal WTSACB is disabled to a logic high level, which is a state that the mode determination signal WTTEDB is enabled to a logic high level and the column selection signal YI<0>is disabled to a logic low level according to the write operation, the first driving signal SAN and the second driving signal SAP are enabled to a logic high level. Then, the bit line sense amplifier 40 amplifies the data loaded on the pair of bit lines BL and /BL, which is a charge-sharing seed data, and maintains the amplified level through a latch operation.

In this state, when a write command WT is applied, a write driver 10 loads a data to be written in the pair of local input/output lines LIO and /LIO, and the data loaded on the pair of local input/output lines LIO and /LIO is loaded on the pair of segment input/output lines SIO and /SIO, too. This is because the first switch 20 is already turned on.

Subsequently, when the column selection signal YI<0>is enabled to a logic high level during a particular duration (e.g., a predetermined duration), the column strobe signal COL_STROBE is also enabled to a logic high level during the particular duration. Accordingly, the control signal WTSACB is enabled to a logic low level during the particular duration, and the first driving signal SAN and the second driving signal SAP are disabled to a logic low level during the particular duration. As a result, the driving of the bit line sense amplifier 40 is ceased.

At the same time, as the column selection signal YI<0>is enabled to a logic high level, the second switch 30 is turned on and the data loaded on the pair of segment input/output lines SIO and /SIO is loaded on the pair of bit lines BL and /BL and eventually loaded on the memory cell 50. Here, since the driving of the bit line sense amplifier 40 is stopped, the data loaded on the pair of segment input/output lines SIO and /SIO is stably loaded on the pair of bit lines BL and /BL without fighting between the write driver 10 and the bit line sense amplifier 40. After all, the data loaded on the pair of bit lines BL and /BL may be stably stored in the memory cell 50 within a duration where the column selection signal YI<0>is enabled.

According to an exemplary embodiment of the present invention described above, even when a data previously stored in a memory cell has an opposite phase to that of the data to be stored currently, a data may be fully written in a corresponding memory cell when the column strobe signal COL_STROBE is enabled.

According to the technology of the present invention, data may be stably stored in memory cells quickly by removing possible fighting between a write driver and a bit line sense amplifier during a write operation of a semiconductor integrated circuit. As a result, the operational reliability of the semiconductor integrated circuit may be improved. Due to the improved yield of the semiconductor integrated circuit, the production amount may be increased and a high-speed operation characteristic may be obtained. In particular, the technology of the present invention is more effective when a data stored previously in a memory cell and a data to be stored currently have an opposite phase to each other.

While the present invention has been described with respect to the specific embodiments, it will be apparent to those skilled in the art that various changes and modifications may be made without departing from the spirit and scope of the invention as defined in the following claims.

For example, although a control circuit for controlling a bit line sense amplifier is taken as an example to describe the scope and concept of the present invention, the scope and concept of the present invention are not limited to the control circuit. Rather, the technology of the present invention may be applied to other circuits including a cross-coupled latch-type sense amplifier.

What is claimed is:

1. A semiconductor integrated circuit, comprising:
a first signal generator configured to generate a third active signal that is selectively enabled in a first duration in response to a first active signal enabled during the first duration and a second active signal enabled during at least one second duration within the first duration;
an internal circuit configured to cease operating in response to the third active signal; and
a second signal generator configured to generate the second active signal in response to a mode determination signal and a strobe signal.

2. The semiconductor integrated circuit of claim 1, wherein the internal circuit is a cross-coupled latch-type sense amplifier.

3. The semiconductor integrated circuit of claim 1, wherein the mode determination signal is a signal for distinguishing a write mode and a read mode from each other.

4. The semiconductor integrated circuit of claim 1, wherein the strobe signal is enabled in response to a burst length.

5. A semiconductor integrated circuit, comprising:
a driving signal generator configured to generate a first driving signal and a second driving signal that are selectively enabled during a first duration in response to first and second enable signals that are enabled during an active operation, an active command-based selection signal that is enabled during the first duration, and a control signal that is enabled during at least one second duration within the first duration;
a bit line sense amplifier (BLSA) configured to be driven in response to the first driving signal and the second driving signal, wherein the BLSA ceases to sense when the first and second driving signals are active; and
a control signal generator for generating the control signal in response to a mode determination signal and a column strobe signal.

6. The semiconductor integrated circuit of claim 5, wherein the mode determination signal is a signal for distinguishing a write mode and a read mode from each other.

7. The semiconductor integrated circuit of claim 5, wherein the column strobe signal is enabled in response to a burst length.

8. The semiconductor integrated circuit of claim 5, wherein the driving signal generator comprises:
a first driving signal generation unit for generating the first driving signal in response to the active command-based selection signal, the first enable signal, and the control signal; and
a second driving signal generation unit for generating the second driving signal in response to the active command-based selection signal, the second enable signal, and the control signal.

9. The semiconductor integrated circuit of claim 8, wherein the first driving signal generation unit comprises:
a first logic operation element for performing a logic operation onto the active command-based selection signal, the first enable signal, and the control signal;
a first level shifting element for shifting a level of an output signal of the first logic operation element; and
a first output element for outputting an output signal of the first level shifting element as the first driving signal.

10. The semiconductor integrated circuit of claim 8, wherein the second driving signal generation unit comprises:
a second logic operation element for performing a logic operation onto the active command-based selection signal, the second enable signal, and the control signal;
a second level shifting element for shifting a level of an output signal of the second logic operation element; and
a second output element for outputting an output signal of the second level shifting element as the second driving signal.

11. The semiconductor integrated circuit of claim 5, wherein the control signal generation unit comprises:
a third logic operation element for performing a logic operation onto the mode determination signal and the column strobe signal; and
a third output element for outputting an output signal of the third logic operation element as the control signal.

12. The semiconductor integrated circuit of claim 5, further comprising:
a selection signal generator configured to generate the active command-based selection signal in response to an upper matrix selection signal and a lower matrix selection signal.

13. The semiconductor integrated circuit of claim 12, wherein the bit line sense amplifier is shared by an upper memory cell matrix and a lower memory cell matrix.

14. The semiconductor integrated circuit of claim 5, further comprising:
a pair of first input/output lines;
a write driver configured to drive the pair of first input/output lines in response to a data to be written;
a pair of bit lines coupled with the bit line sense amplifier; and
a first switch configured to selectively couple the pair of first input/output lines and the pair of bit lines in response to a column selection signal.

15. The semiconductor integrated circuit of claim 14, wherein the pair of first input/output lines comprises:
a pair of local input/output lines coupled with an output end of the write driver; and
a pair of segment input/output lines coupled with one end of the first switch.

16. The semiconductor integrated circuit of claim 15, further comprising:
a second switch configured to selectively couple the pair of local input/output lines with the pair of segment input/output lines in response to an input/output line coupling signal.

17. A method for driving a semiconductor integrated circuit, comprising:
entering a write mode;
stopping an operation of a bit line sense amplifier in the write mode;
loading a data on a pair of bit lines while the operation of the bit line sense amplifier is stopped; and
writing the data loaded on the pair of bit lines in a memory cell.

18. The method of claim 17, wherein the stopping of the operation of the bit line sense amplifier in the write mode is performed during a column selection duration enabled in response to a burst length.
